(19) United States
(12) Patent Application Publication
(10) Pub. No.: US 2008/0156638 A1
(43) Pub. Date: Jul. 3, 2008

(54) Process for sputtering aluminum or copper onto aluminum or magnalium alloy substrates

(76) Inventor: Shuixiang Huang, Kunshan City (CN)

Correspondence Address: Raymond Y. Chan, Suite 128, 108 N. Ynez, Monterey Park, CA, 91754, US

(21) Appl. No.: 11/998,211

(22) Filed: Nov. 28, 2007

(30) Foreign Application Priority Data
Dec. 27, 2006 (CN) 200610155936.7

(51) Int. Cl. C23C 14/14

(52) U.S. Cl. 204/192.14

(57) ABSTRACT

A method of sputtering a metal substance onto at substrate selected from the group consisting of at least one of aluminum and magnalium alloy, includes the steps of: cleaning a surface of the substrate by tap water and R.O. water; coating a base coat on the surface of the substrate; coating a media coat over the base coat, wherein the media coat includes a mixture of poly-butadiene resin, alkyd, and toluene; sputtering the metal substance over the media coat by Physical Vapor Deposition (PVD) process to form a metal layer on the media coat, wherein the metal substance is selected from the group consisting of aluminum and copper; and coating a top coat over the metal layer.

### BACKGROUND OF THE PRESENT INVENTION

1. Field of Invention

The present invention relates to a process of providing a mirror-like, rich-colored, glossy metal finish onto substrates, and more particularly to a process for sputtering aluminum or copper onto aluminum or magnalium alloy substrate, wherein the process is adapted to utilize in field of automotive rims, computer casings, and mobile phone casings to provide a surface coating with better wear-resistance, thermo-resistance and rich textured surface protection.

2. Description of Related Arts

The process for applying aluminum or copper coating on aluminum or magnalium alloy substrates is normally using in the production of vehicle rims, computer casings, cell-phone casings etc. In the past, aluminum and aluminum-magnesium alloy automotive wheels have traditionally been electroplated to produce chrome rims. The electroplating process requires the rim to be well-polished to provide a very smooth surface for effectively plating the copper, nickel and chrome. Furthermore, the rims must be pretreated in hazardous chemical to provide a clean homogeneous surface for adherence of the chrome plating. The rims are then coated with up to three different metal coatings (two of them are chromium and nickel), wherein each coating step requires the rim being submerged in hazardous chemical solutions. The failure rate of the prior art process is generally highs. In addition, hazardous solutions are required in each coating step and heavy metals such as chromium and nickel are applied as necessary coatings. Therefore, it causes serious pollution into the environment. Additionally, once the chrome plated surface is damaged, the rim will start to corrode and rust rapidly and the chrome plating will be delaminated from the rim surface.

U.S. Pat. No. 6,399,152 disclosed a vacuum metallization process for chroming substrates, wherein the process includes a first step of cleaning a surface of a substrate prior to applying the stabilizing metallic layer, a second step of applying all organic, epoxy, thermosetting, powder of a base coat oil the substrate surface, a third step of applying a Chromium metallic layer over a Nickel/Chromium metallic layer on the base coat through PVD (Physical Vapor Deposition) technique, and the fourth step of applying an organic, acrylic, thermosetting powder topcoat over the Chromium layer. Even though the above improved process is adapted to reduce the possibility of delamination of the chrome plating, chromium and nickel as two major materials are still used in the process. Therefore, similar to the electroplating process, the vacuum metallization process will also create serious pollution by such heavy metal materials. In the 21st century that environmental protection is greatly emphasized, the products like such made of highly-polluting material and producing serious pollutants also will cause second pollution has not been accepted by USA and most European countries. During the PVD step, problems such as insulation base coat and thermosetting ability will cause the low adhesion between the base coat and metal layer under the effect of common magnetization as well as the metal layer becomes yellowish.

### SUMMARY OF THE PRESENT INVENTION

An object of the present invention is to provide a process for applying aluminum or copper coating on aluminum or magnalium substrates to overcome the difficulties and shortcomings of the prior art such as high pollution, less thermosetting ability, lack of adhesion, easy to have common magnetization effect, and weak in decoration.

Accordingly, in order to accomplish the above objects, the present invention provides a method of coating aluminum or copper onto aluminum or aluminum magnalium alloy substrates, the method comprises the following steps.

The first step is the preparation of the surface of the substrate comprising the steps of:

(a) polishing the surface of the substrate;

(b) washing by tap water;

(c) washing by R.O. water;

(d) blow drying by high pressure filtered air;

(e) heat drying; and

(f) cooling.

The second step is coating the base coat by the steps of:

(a) coating base coat over the substrate, wherein the base coat comprises:

| | |
|---|---|
| Acrylic resin | 21~39% (weight); |
| Epoxy | 14~26% (weight); |
| Amino resin | 7~13% (weight); |
| Carbon powder | 21~39% (weight); |
| Organic solvents | rest; |

(b) leaving the coat to be flattened;

(c) heating the substrate to 90° C.-190° C.; and

(d) cooling.

The third step is coating the media coat, which comprises the steps of:

(a) coating media coat over base coat, the media coat comprises:

| | |
|---|---|
| Poly-butadiene resin | 33.6~62.4% (weight); |
| Alkyd | 1.2~2.2% (weight); |
| Toluene | rest; |

(b) leaving the coat to be flattened;

(c) heating the substrate to 110° C.-200° C.; and

(d) cooling;

The fourth step is PVD process.

The PVD process is utilizing vacuum cathode magnetron sputtering to coat aluminum or copper onto the substrates. When applying aluminum target, the pressure in the chamber is 0.7×10⁻⁵˜1.3×10⁻⁵ mTorr before sputtering, the amount of argon is 45R to 90R, using DC, the voltage applied is 400V to 1000V, the current is 70 A to 130 A.

When applying copper target, the pressure in the chamber is 0.7×10⁻⁵˜1.3×10⁻⁵ mTorr before sputtering, the amount of argon is 14R to 26R, using DC, the voltage applied is 400V to 1000V, the current is 3.5 A to 10 A.

The fifth step is coating top coat by the steps of:

(a) coating top protection coat over the aluminum or copper coat;

(b) heat drying after the top protection coat is flattened;

(c) cooling.

The detail explanation of the present invention is:

1. In this process, “mTorr” is a vacuum (pressure) unit, 1 torr-=1 mmHg=133 Pa. R is the is constant of argon, from the Clapeyron Equation of Ideal Gas Law, P·V=n·R·T, we know P·V=n·R·T, it ideal status, R=8.3145 J/(mol·K).

2. In the first step, R.O. water is a kind of deionized purified water.

3. In the fourth step, the sputtering time of aluminum and copper is 120˜300 s. During the PVD process, the color of the aluminum or copper coating, call be changed by adjusting the current, the amount of argon, and the sputtering time.

4. In the fourth step, the principle of the vacuum cathode magnetron sputtering is utilizing glow-discharging to let argon ion to bombard the surface of the target, the cation of the plasma is accelerated towards the cathode which is used as the coating material, the atoms of the target are ejected by the collision and then deposited on the substrate to form a thin film.

5. In the fifth step, the top coat is using polymethyl methacrylate acrylic resin (PMMA). The PMMA with good quality is called acryl, with bad quality (formed by cracking renewable materials casting) is called plexiglass. This coat is a glass like transparent resin (plastic). The acryl is light, colorful, its surface hardness is like aluminum alloy, harder than other resin, and has better wear resistance; it also has good flexibility and plasticity, easy to be processed, and good resistance to wearness and chemicals.

6. In the second step, the preferred component of the base coat is:

| | |
|---|---|
| Acrylic resin | 27~33% (weight); |
| Epoxy | 18~22% (weight); |
| Amino resin | 9~11% (weight); |
| Carbon powder | 27~33% (weight); |
| Organic solvents | rest. |

7. In the second step, before coating, the substrates are preferred to be pre-heated, the temperature should not higher than 55° C.

8. In the third step, the preferred component of the media coat is:

| | |
|---|---|
| Poly-butadiene resin | 43.2~52.8% (weight); |
| Alkyd | 1.5~1.9% (weight); |
| Toluene | rest. |

9. In the third step, before coating, the substrates are preferred to be pre-heated, the temperature should not higher than 60° C.

10. In the first step, in a preferred embodiment, the surface of the substrate is washed by tap water at temperature of 50° C.-60° C. twice, then is washed by tap water at room temperature twice, and finally is washed by R.O. water twice.

The principles and characteristics of the present invention are: according to the special aluminum and magnalium substrates, utilizing the special property, such as thermal resistance and insulation, of poly-butadiene resin in media coat; using ultra high vacuum magnetic control sputtering; by changing the parameters of current, Argon and sputtering time in PVD stage, the appearance color of product can be altered combining the color of base coat. The process comprises five stages: (1) Cleaning or Preparation Stage, (2) Base Coat Application Stage, (3) Media Coat Application Stage, (4) PVD Stage and (5) Top Coat Application Stage.

The cleaning stage begins by smoothing the substrate to provide a uniform surface roughness. Next, a series of washes are performed to the substrate, followed by a R.O. water rinse. The substrate is then dried using high-pressure filtered air and is subsequently placed in an oven to be outgassed. Last, the wheel is allowed to cool down. In the cleaning or preparation stage, no alkaline or acid solution is required to build a coating for the substrate. The process only requires clean water and R.O. water.

The base coat applied in the base coat application stage is different colored resin or the like to provide different appearance color combining with that of metal layer according to the final appearance require. For example, the color combination of black base coat and copper layer can provide a royal blue metalizing appearance.

The media coat applied in the media coat application stage is poly-butadiene resin or the like, its unique richness provides a smooth and rich surface for the adhesion of AL or CU layer. The thermosetting ability of poly-butadiene resin solves the yellow-changing problem in the use of the product. Its unique insulating ability prevents the common magnetization effect in the PVD stage.

To begin the PVD stage, the substrate is placed into a PVD chamber to receive the aluminum or copper coating layer. The step takes place in vacuum conditions and by a sputtering or similar process. The step compromises sputtering aluminum or copper atoms onto the media coat (poly-butadiene resin or the like) through UHV magnetron sputtering. By changing the parameters of current, argon and time to control the appearance color of the metal layer.

In the top coat application stage, a clear resin is applied as top coat so as to reveal the superior gloss and metal richness. The top coat is applied to the substrate to cover the aluminum or copper layer and is subsequently heated to cause crosslinking and solidification. The substrate is then permitted to cool down to fully protect the metal layer.

The present invention has the following advantages:

1. No hazardous material is used in the cleaning stage and no alkaline, phosphate, chromate or such chemical is required to establish coating. The process is environmentally compatible, using no heavy metal such as Chromium and Nickel. The process is environmental friendly, meeting with the developing trend in the world and future.

2. Due to the insulation property of poly-butadiene resin, the process overcomes the common magnetization effect between sputtering machine and substrate, increases the adhesion between the metal thin film and the substrate; and also solved the color-changing problem (yellowish) and peeling problem by the good thermosetting ability of the poly-butadiene resin. For example, the vehicle wheel will generate a large amount of heat during braking, but the thermosetting ability of the poly-butadiene resin prevents it from changing yellow; the process makes use of the rich appearance of poly-butadiene resin to increase the gloss of the finish to be mirror-like.

3. By changing the parameters of current, argon and sputtering time in PVD stage, the appearance color of product can be altered combining the color of base coat. It largely improve the appearance of normal electroplating surfaces, generates a mirror-like, colorful, high gloss electroplating effect.

4. The process uses no heavy metal materials such as chromium and nickel, product using this process will not cause second pollution to the environment when during recycling, discarding, replacing when the usage period is expired.

In summary, the invention relates to a process of UVH sputtering combining with the unique property of poly-butadiene resin, having superior appearance and performance such as adhesion and hardness. The process of the present invention permits a decorative, aluminum or copper coating to be applied to a metal object, for example an aluminum or magnalium vehicle wheel, cell phone parts and computer covers.

These and other objectives, features, and advantages of the present invention will become apparent from the following detailed description, the accompanying drawings, and the appended claims.

### BRIEF DESCRIPTION OF THE DRAWINGS

FIG. 1 is a flow diagram of the process for sputtering aluminum or copper onto aluminum or magnalium alloy substrates.

### DETAILED DESCRIPTION OF THE PREFERRED EMBODIMENT

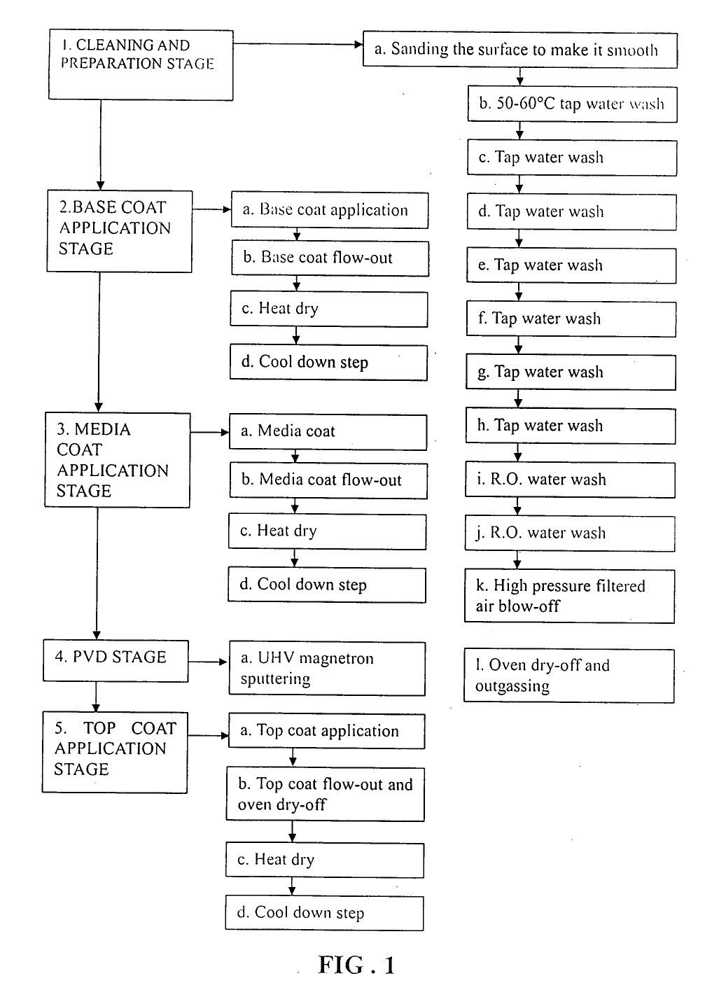

The sputtering of aluminum or magnalium vehicle wheels will be used herein to describe the process stages and steps of the invention. As shown in FIG. 1, the five general steps of the process are as follows: 1) Cleaning or Preparation Stage, 2) Base Coat Application Stage, 3) Media Coat Application Stage, 4) PVD Stage and 5) Top Coat Application Stage.

1) Cleaning and Preparation Stage

The cleaning and preparation is shown in FIG. 1. The surface of the substrate is initially smoothed by a blast media with coarseness not greater than P400. This process step provides a substrate surface that is congenial for the richness and adhesion of base coat application.

The wheel is next put through a multi-step, spray washer type for cleaning. First step is an approximately 60-second wash cycle of tap water with temperature at 50° C.-60° C. This cleaning step is to remove any contamination that may be present on the substrate surface. The next six consecutive steps are spray wash of tap water in environment temperature with each step at approximately 45 seconds to ensure the wheel is totally clean before entering R.O. water wash step. The testing shows spray wash with six consecutive steps is more effective than one long-time wash. The last two steps are wash cycle of R.O water, replacing the tap water present on the surface to ensure the mineral contained in water drop remaining on the surface is not greater than 20 ppm.

Excess water is next blown off by filtered air before entering a dry-off oven. The wheel is heated in the dry-off oven to a temperature of approximately 150° C.-160° C. The latter step serves two purposes: it evaporates any moisture on the wheel left from pretreatment process and it causes the pores in aluminum or magnalium substrate to outgas any contamination and/or trapped vapors will not release during the heating steps required in the base and top coat application stages. The wheel then enters a cooling line letting it cool naturally to ensure the surface temperature is not more than 55° C., in preparation for the base Coat application.

2) Base Coat Application

The wheel is coated in horizontal face up position to ensure even and smooth coverage. The base coal used in this step comprises:

| | |
|---|---|
| Acrylic resin | 30% (weight); |
| Epoxy | 20% (weight); |
| Amino resin | 10% (weight); |
| Carbon powder | 30% (weight); |
| Flow-agent | 1% (weight); |
| Organic agent | rest. |

The pre-heating time is ensured at about 13-15 min. The wheel temperature is not higher than 55° C. when applied base coat. Then placed still for 15-20 min after applying the base coat, the wheel is heated again to 150° C.-175° C. for a period of approximately 30 min. Then the wheel is cooled.

3) Media Coat Application

The Media Coat Used in this Comprises:

| | |
|---|---|
| Poly-butadiene resin | 48% (weight); |
| Alkyd | 1.7% (weight); |
| Flow-agent | 1.3% (weight); |
| Toluene | rest. |

The pre-heating time is ensured at about 13-15 min. The wheel temperature is not higher than 60° C. when applied base coat. Then placed still for 20-30 min after applying the media coat to ensure the smooth flow-out, the wheel is heated again to 170° C.-185° C. for a period of approximately 30-35 min. The thickness of the media coat is generally 30-35 mils, the advantage of which is the thermosetting, insulating and richness ability of the media coat (with majority of poly-butadiene) can fully be achieved. Variation in time, outside the parameters will typically result in al uneven, wavy or orange peal type finishes.

4) PVD Stage

The wheel is next placed into a Physical Vapor Deposition (PVD) chamber for metallization. The chamber is equipped with aluminum target or copper target. The wheel is rotated on its axes in the chamber. The pressure in the chamber is then reduced to create a vacuum environment. When applying aluminum target, the voltage is set to be 600V, the current is set to be 105 A, argon of approximately 65R-70R is injected into the chamber to ensure the appropriate gloss of the aluminum coating layer. Aluminum is applied by sputtering for 210 seconds. Before sputtering, the pressure in the chamber should be kept about 10⁻⁵ mTorr. The purity of aluminum target should be 99.99%. At the same time, variation in current and Argon quantity may result in the change of the property of aluminum target so as to produce different metallization appearances.

When applying copper target, the pressure in the chamber should be kept about 10⁻⁵ mTorr before sputtering. During sputtering, the voltage is set to be 600V, the current is set to be 5 A, argon of approximately 20R is injected into the chamber. Copper target can be divided as copper and brass. Generally, at certain vacuum condition, variation in current, argon quantity and sputtering time may result in different metallization appearances.

5) Top Coat Application

The purpose of the top coat is to provide protection to the metal coating, wear resistance and UV protection. The top coat of the invention is a clear acryl resin. The wheel is pre-heated to 30° C.-100° C. before applying the top coat. After top coat application, the wheel is heated again to 150° C.-170° C. The thickness of top coat is approximately 30-35 mils.

The testing result of the wheel used this process is follows:

| | | |
|---|---|---|
| 1. Salt Spray | | 1000H |
| 2. Adhesion | 10 × 10 mm | OK |
| 3. Pencil Hardness | 45°, 5 times | H |
| 4. Water Immersion | | OK |
| 5. Acid Spray | | 96H |

In summary, the preferred embodiment the process utilizes the special property of poly-butadiene resin in media coat, UHV sputtering aluminum or copper onto the surface of aluminum or magnalium substrates. By changing the parameters of current, Argon and sputtering time in PVD stage, the appearance color of product can be altered combining the color of base coat. The process utilizes the thermosetting, insulating and rich ability to combine and improve the traditional painting and chroming process so as to provide a decorative, durable, yellow-changing resistant and environmentally friendly aluminum or copper finish, for example vehicle wheels.

One skilled in the art will understand that the embodiment of the present invention as shown in the drawings and described above is exemplary only and not intended to be limiting.

It will thus be seen that the objects of the present invention have been fully and effectively accomplished. The embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A method of sputtering a metal substance onto a substrate selected from the group consisting of aluminum and magnalium alloy, comprising the steps of:
(a) coating a base coat on a surface of said substrate;
(b) coating a media coat over said base coat, wherein said media coat comprises a mixture of poly-butadiene resin, alkyd, and toluene;
(c) sputtering said metal substance over said media coat by Physical Vapor Deposition (PVD) process to form a metal layer oil said media coat, wherein said metal substance is selected from the group consisting of aluminum and copper; and
(d) coating a top coat over said metal layer.

2. The method as recited in claim 1 wherein, in the step (c), said PVD process is using vacuum cathode magnetron sputtering to coat said metal substance onto said substrate.

3. The method as recited in claim 1 wherein, in the step (a), said base coat comprises a mixture of acrylic resin, epoxy, amino resin, carbon powder, and organic solvent.

4. The method as recited in claim 2 wherein, in the step (a), said base coat comprises a mixture of acrylic resin, epoxy, amino resin, carbon powder, and organic solvent.

5. The method, as recited in claim 4, wherein a ratio of said acrylic resin, epoxy, amino resin, and carbon powder is 21˜39%:14˜26%:7˜13%:21˜39% by weight.

6. The method, as recited in claim 1, wherein a ratio of poly-butadiene resin, alkyd and toluene is 33.6˜62.4%:1.2˜2.2% by weight.

7. The method, as recited in claim 2, wherein a ratio of poly-butadiene resin alkyd and toluene is 33.6˜62.4%:1.2˜2% by weight.

8. The method, as recited in claim 5, wherein a ratio of poly-butadiene resin, alkyd and toluene is 33.6˜62.4%:1.2˜2.2% by weight.

9. The method as recited in claim 1, before the step (a), further comprising a cleaning step of cleaning said surface of said substrate by tap water and R.O. water.

10. The method as recited in claim 2, before the step (a), further comprising a cleaning step of cleaning said surface or said substrate by tap water and R.O. water.

11. The method as recited in claim 8, before the step (a), further comprising a cleaning step of cleaning said surface of said substrate by tap water and R.O. water.

12. The method, as recited in claim 9, wherein said cleaning step comprises the steps of:
polishing said surface of said substrate;
first time washing said surface of said substrate by tap water;
second time washing said surface of said substrate by R.O. water;
blow drying said surface of said substrate by filtered air;
heat drying said surface of said substrate; and
cooling said surface of said substrate for said base coat coating thereon.

13. The method, as recited in claim 10, wherein said cleaning step comprises the steps of:
polishing said surface of said substrate;
first time washing said surface of said substrate by tap water;
second time washing said surface of said substrate by R.O. water;
blow drying said surface of said substrate by filtered air;
heat drying said surface of said substrate; and
cooling said surface of said substrate for said base coat coating thereon.

14. The method, as recited in claim 11, wherein said cleaning step comprises the steps of:
polishing said surface of said substrate;
first time washing said surface of said substrate by tap water;
second time washing said surface of said substrate by R.O. water;
blow drying said surface of said substrate by filtered air;
heat drying said surface of said substrate; and
cooling said surface of said substrate for said base coat coating thereon.

15. The method as recited in claim 1 wherein, in the step (c), the metallization appearances of said sputtering is adjusted by altering one of amount of argon, sputtering time, and an operation current of said PVD process.

16. The method as recited in claim 4 wherein, in the step (c), the metallization appearances of said sputtering is adjusted by altering one of amount of argon, sputtering time, and an operation current of said PVD process.

17. The method as recited in claim 14 wherein, in the step (c), the metallization appearances of said sputtering is adjusted by altering one of amount of argon, sputtering time, and an operation current of said PVD process.

18. The method, as recited in claim 1, wherein said top coat comprises polymethyl methacrylate acrylic resin coating on said metal layer.

19. The method, as recited in claim 4, wherein said top coat comprises polymethyl methacrylate acrylic resin coating on said metal layer.

20. The method, as recited in claim 17, wherein said top coat comprises polymethyl methacrylate acrylic resin coating on said metal layer.
